(19) United States
(12) Patent Application Publication
(10) Pub. No.: US 2025/0273436 A1
(43) Pub. Date: Aug. 28, 2025

(54) SUBSTRATE EDGE PROFILE TREATMENT

(71) Applicant: Applied Materials, Inc., Santa Clara, CA (US)

(72) Inventors: Dmitry LUBOMIRSKY, Cupertino, CA (US); Ellie Y. YIEH, San Jose, CA (US)

(21) Appl. No.: 18/588,898

(22) Filed: Feb. 27, 2024

(51) Int. Cl. H01J 37/32; H01L 21/683; H01L 21/687

(52) U.S. Cl. CPC H01J 37/32385; H01J 37/3244; H01J 37/32642; H01J 37/32715; H01J 37/32733; H01L 21/6831; H01L 21/68735; H01J 2237/3343

(57) ABSTRACT

Embodiments described herein relate to a method of treatment for substrate edge profiles. The method including generating a plasma in a plasma processing region of a processing volume of a processing chamber where the processing volume includes a first volume disposed above a grid assembly to receive a plasma and a second volume containing a substrate support assembly disposed below the grid assembly for processing a substrate. The grid assembly includes one or more grid plates; each grid plate including a plurality of perforations of two or more perforations arranged along a circular path disposed over a peripheral region of a substrate support surface. The method includes exposing the peripheral region of the substrate support surface to a plasma species generated in the first volume by focusing the plasma species through the perforations onto the peripheral region of the substrate support surface in the second volume.

### BACKGROUND

### Field

Embodiments of the present disclosure generally relate to a method of plasma etching. More specifically, embodiments described herein relate to a method of treatment for substrate edge profiles.

### Description of the Related Art

Semiconductor manufacturing encompasses a series of intricate processes aimed at creating integrated circuits (ICs) and other semiconductor devices. Generally, the process begins with crystal growth, where methods like the Czochralski and Float-Zone techniques yield high-quality silicon wafers. Following wafer preparation through slicing, lapping, and polishing, the wafers undergo oxidation, forming insulating silicon dioxide layer, photolithography comes next, involving photoresist coating, exposure through a photomask, and development to define patterns on the wafer. Etching processes, including dry and wet methods, selectively remove material based on the photolithographic pattern. Deposition techniques like Chemical Vapor Deposition (CVD) and Physical Vapor Deposition (PVD) add thin films to the wafer surface.

Ion implantation modifies the wafer's electrical properties, and subsequent annealing repairs damage caused by the implantation process. Chemical Mechanical Polishing (CMP) ensures a flat and smooth wafer surface, crucial for precision. Device isolation methods, such as shallow trench isolation or local oxidation of silicon, are employed to electrically isolate different components on the same wafer. Metallization involves depositing and patterning metal layers to create interconnects between various parts of the semiconductor device. Further steps include ion implantation, annealing, chemical mechanical polishing, and device isolation. The final stages encompass packaging, where individual devices are cut, packaged, and tested before assembly into the final products. These processes are highly intricate, with advanced technologies introducing additional steps to enhance device performance and reduce feature sizes, such as multiple patterning, FinFET fabrication, and extreme ultraviolet (EUV) lithography.

Each of the above process steps relies on the precision and accuracy of the steps preceding it. While each of the above process steps may be performed within the mandated tolerances, over successive steps, errors may build-up, a phenomenon known as tolerance stacking. Tolerance stacking may lead to issues which may result in non-concentricity between the layers formed on the substrate and the substrate itself which may lead to die or yield losses. Current methods of dealing with non-concentricity rely on etching the outer profiles of the layers and substrate using blocking plates and substrate frontside purging to protect the central area of the substrate from etching. These methods however, may cause the profile of the exposed layers and substrate to be etched in undesirable ways due to poor plasma control. Accordingly, new methods and devices are needed in the art for treatment of substrate edge profiles.

### SUMMARY

Embodiments of the present disclosure generally relate to a method of plasma etching. More specifically, embodiments described herein relate to a method of treatment for substrate edge profiles.

In one embodiment, a plasma processing system is provided. The plasma processing system includes a processing chamber may include one or more sidewalls defining a processing volume. The plasma processing system includes a grid assembly may include one or more grid plates, where the grid assembly divides the processing volume into a first volume disposed above the grid assembly to receive a plasma and a second volume disposed below the grid assembly for processing a substrate, where each grid plate of the one or more grid plates may include a first surface. The plasma processing system includes a second surface, disposed opposite of the first surface, and a plurality of perforations extending between the first surface and the second surface, where the plurality of perforations may include a first pattern of two or more perforations arranged along a circular path disposed over a peripheral region of a substrate support surface of a substrate support assembly disposed in the second volume, the first pattern may include one or more concentric rows of perforations, where each row of the one or more concentric rows is spaced radially from a center of the one or more grid plates, each row of the one or more concentric rows include at least one perforation. The plasma processing system includes where the plurality of perforations of each grid plate of the one or more grid plates are vertically aligned to the plurality of perforations of each other grid plate of the one or more grid plates.

In another embodiment, a method of substrate processing is provided. The method includes generating a plasma in a plasma processing region of a processing volume of a processing chamber, where the processing volume is defined by a chamber lid, a chamber base, and one or more sidewalls, where the processing volume may include a first volume disposed above a grid assembly to receive a plasma and a second volume disposed below the grid assembly for processing a substrate, where the grid assembly may include one or more grid plates, where each grid plate of the one or more grid plates may include a first surface. The method includes a second surface, disposed opposite of the first surface, and a plurality of perforations extending between the first surface and the second surface, where the plurality of perforations may include a first pattern of two or more perforations arranged along a circular path disposed over a peripheral region of a substrate support surface of a substrate support assembly disposed in the second volume, the first pattern may include one or more concentric rows of perforations, where each row of the one or more concentric rows is spaced radially from a center of the grid plate, each row of the one or more concentric rows include at least one perforation. The method includes where the plurality of perforations of each grid plate of the one or more grid plates are vertically aligned to the plurality of perforations of each other grid plate of the one or more grid plates. The method includes exposing the peripheral region of the substrate support surface to a plasma species generated in a plasma in the first volume by focusing the plasma species through the plurality of perforations onto the peripheral region of the substrate support surface.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1B are schematic cross-sectional views of a plasma processing system, according to one or more embodiments, configured to practice the methods set forth herein.

FIGS. 2A-2B are schematic views of a device substrate, according to one or more embodiments described herein.

FIGS. 3A-3B are schematic views of a grid plate of a plasma processing system, according to one or more embodiments described herein.

FIG. 4 is a schematic cross-sectional view of a plasma processing system, according to one or more embodiments, configured to practice the methods set forth herein.

FIG. 5 is a schematic cross-sectional view of a plasma processing system, according to one or more embodiments, configured to practice the methods set forth herein.

FIG. 6 is a schematic cross-sectional view of a plasma processing system, according to one or more embodiments, configured to practice the methods set forth herein.

FIG. 7 is a process flow diagram of a method of operations, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Each process step in semiconductor manufacturing relies on the precision and accuracy of the steps preceding it. While each process step may be performed within the mandated tolerances, over successive steps, errors may build-up, a phenomenon known as tolerance stacking. Tolerance stacking may lead to issues which may result in non-concentricity between the layers formed on the substrate and the substrate itself which may lead to die or yield losses. Current methods of dealing with non-concentricity rely on etching the outer profiles of the layers and substrate using blocking plates and substrate frontside purging to protect the central area of the substrate from etching. These methods however, may cause the profile of the exposed layers and substrate to be etched in undesirable ways due to poor plasma control. Accordingly, new methods and devices are needed in the art for treatment of substrate edge profiles.

### Plasma Processing System Example

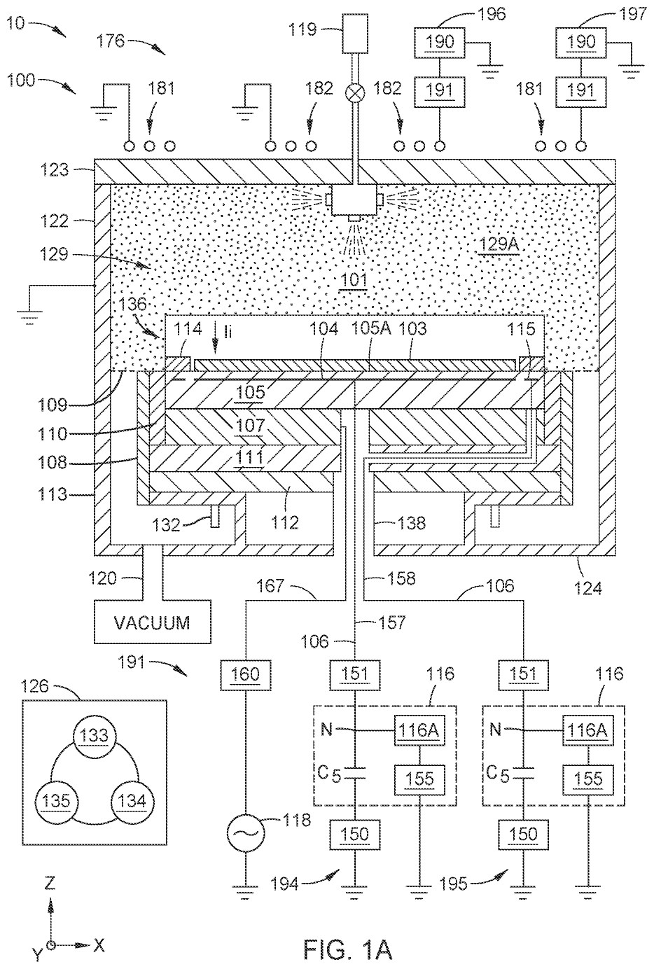

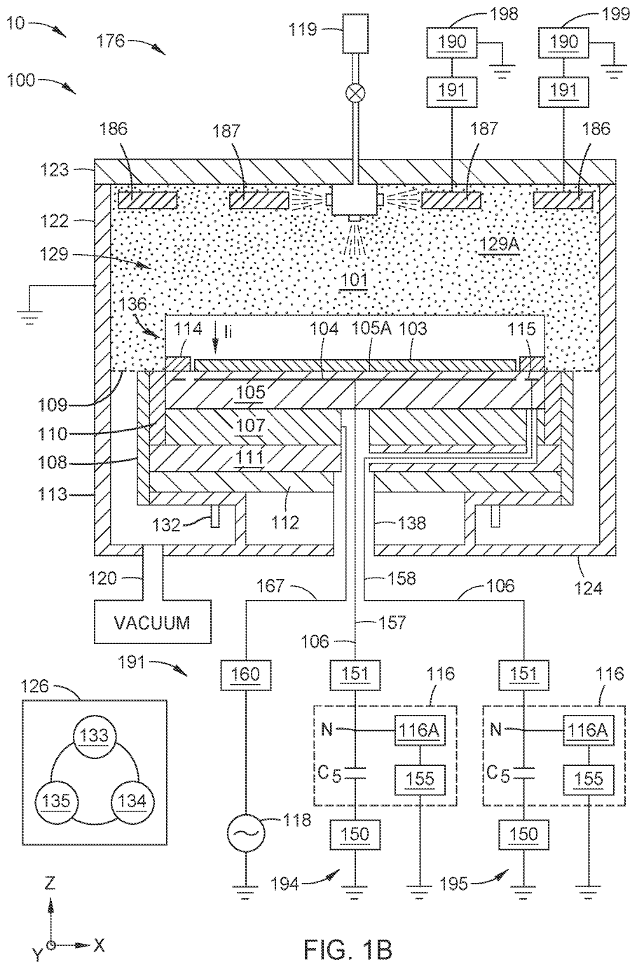

FIG. 1A is a schematic cross-sectional view of a plasma processing system 10 that is configured to perform one or more of the plasma processing methods set forth herein. In some embodiments, the plasma processing systems 10 are configured for plasma-assisted etching processes, such as a reactive ion etch (RIE) plasma processing. However, it should be noted that the embodiments described herein may be also be used with processing systems configured for use in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

The plasma processing system 10 generally includes a processing chamber 100, a lid assembly 176, a substrate support assembly 136, and a system controller 126. As shown, the plasma processing system 10 includes a plurality of plasma source assemblies that are each adapted to deliver a voltage waveform to one or more electrodes and/or one or more coils disposed within the processing chamber 100. In one configuration example, as shown in FIG. 1, the processing chamber 100 includes plasma source assemblies, such as a first inductively coupled plasma (ICP) assembly 196, and a second inductively coupled plasma (ICP) assembly 197 that each include a RF waveform generator 190 that is adapted to deliver an RF waveform, which is described in more detail below. In another configuration example, as shown in FIG. 1B, the processing chamber 100 includes a first capacitively coupled plasma (CCP) assembly 198, a second capacitively coupled plasma (CCP) assembly 199, a third capacitively coupled plasma (CCP) assembly 198, and a fourth capacitively coupled plasma (CCP) assembly 199 that each include a pulsed voltage (PV) waveform generator 150 that is adapted to deliver an asymmetric voltage waveform.

The processing chamber 100 typically includes a chamber body 113 that includes one or more sidewalls 122 and a chamber base 124, which collectively, with the chamber lid 123 of the lid assembly 176, define the processing volume 129. The one or more sidewalls 122 and chamber base 124 generally include materials that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy. A gas inlet 128 disposed through the chamber lid 123 is used to deliver one or more processing gases to the processing volume 129 from a processing gas source 119 that is in fluid communication therewith. The one or more processing gases may include, but are not limited to, inert gasses, fluorine-containing gasses, hydrogen-containing gases, or any combination thereof. A substrate 103 is loaded into, and removed from, the processing volume 129 through an opening (not shown) in one of the one or more sidewalls 122, which is sealed with a slit valve (not shown) during plasma processing of the substrate 103.

The system controller 126, also referred to herein as a processing chamber controller, includes a central processing unit (CPU) 133, a memory 134, and support circuits 135. The system controller 126 is used to control the process sequence used to process the substrate 103, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the plasma processing system 10. Typically, the software program, which is readable by CPU 133 in the system controller 126, includes code, which, when executed by the processor (CPU 133), performs tasks relating to the plasma processing methods described herein. The program may include instructions that are used to control the various hardware and electrical components within the plasma processing system 10 to perform the various process tasks and various process sequences used to implement the methods described herein.

In some embodiments, the lid assembly 176 includes a chamber lid 123 and the one or more plasma source assemblies, such as two inductively coupled plasma (ICP) assemblies 196, 197 illustrated in FIG. 1A. As shown in FIG. 1A, each ICP assembly 196, 197 includes a coil 181, 182, respectively, that is configured to inductively couple a radio frequency (RF) waveform generated by a RF waveform generator 190 to generate, by excitation, a plasma 101 formed in the processing volume 129 of the processing chamber 100 during plasma processing. In this configuration, the chamber lid 123 includes a dielectric material that is configured to allow the fields generated by the coils 181, 182 during the delivery of a voltage waveform by the RF waveform generator 190 to help generate and sustain the plasma 101 in the processing volume 129. In some embodiments, the chamber lid 123 can include a dielectric material or structural material (e.g., metal) that is configured to withstand the vacuum created in the processing volume 129 during processing. In some embodiments, the RF waveform generators 190 is configured to deliver an RF signal to one or more of the coils 181, 182 within the processing chamber 100, to initially generate (e.g., ignite), by excitation, and maintain, the plasma 101 in a processing volume 129. In some embodiments, the RF waveform generator 190 is configured to deliver an RF waveform signal having a frequency that is greater than 1 MHz or more, or about 2 MHz or more, such as about 13.56 MHz or more through an RF match 191 that is connected to an RF electrode or coil.

In some other embodiments, as shown in FIG. 1B, the lid assembly 176 includes the chamber lid 123 and one or more of the capacitively coupled plasma (CCP) assemblies, such as the two capacitively coupled plasma (CCP) assemblies 198, 199 illustrated in FIG. 1B. As shown in FIG. 1B, each CCP assembly 198, 199 includes an electrode 186, 187, respectively, that is configured to capacitively couple a radio frequency (RF) waveform generated by a RF waveform generator 190 to a plasma 101 formed in the processing volume 129 of the processing chamber 100 during plasma processing. In this configuration, the chamber lid 123 can include a dielectric material or structural material (e.g., metal) that is configured to withstand the vacuum created in the processing volume 129 during processing.

The substrate support assembly 136, as shown in FIGS. 1A-1B, includes a substrate support 105 (e.g., ESC substrate support) and one or more lower electrodes, which are coupled to a plasma source, such as the capacitively coupled plasma (CCP) assemblies 198, 199. In some embodiments, the substrate support assembly 136 can additionally include a support base 107, an insulator plate 111, and a ground plate 112. The support base 107 is electrically isolated from the chamber base 124 by the insulator plate 111, and the ground plate 112 is interposed between the insulator plate 111 and the chamber base 124. The substrate support 105 is thermally coupled to and disposed on the support base 107. In some embodiments, the support base 107 is configured to regulate the temperature of the substrate support 105, and the substrate 103 disposed on the substrate support 105, during substrate processing. Typically, the substrate support 105 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof.

In embodiments herein, the substrate support 105 further includes the bias electrode 104 embedded in the dielectric material thereof. The one or more lower electrodes can include a bias electrode 104 and/or an edge control electrode 115 that are formed within the substrate support 105, and are coupled to one or more plasma source assemblies, such as the PV source assemblies 194, 195. The PV source assembly 194 is coupled to the bias electrode 104 and the PV source assembly 195 is coupled to the edge control electrode 115, and are each configured to deliver a PV waveform generated by a PV waveform generator 150 to a plasma 101 formed in the processing volume 129 of the processing chamber 100 during plasma processing.

In another embodiment, shown in FIG. 1B, The one or more lower electrodes can include a bias electrode 104 and/or an edge electrode 115 that are formed within the substrate support 105, and are coupled to one or more plasma source assemblies, such as the capacitively coupled plasma (CCP) assemblies, such as the two CCP assemblies 198, 199. The CCP assembly 198 is coupled to the bias electrode 104 and the CCP assembly 199 is coupled to the edge electrode 115, and are each configured to deliver a PV waveform generated by a PV waveform generator 150 to a plasma 101 formed in the processing volume 129 of the processing chamber 100 during plasma processing In one embodiment, which is not shown in FIGS. 1A-1B, a PV waveform generator 150 of PV source assembly 194 is configured to bias both the bias electrode 104 and the edge control electrode 115, and thus the PV source assembly 195 and its components are not needed to deliver PV waveforms to the bias electrode 104 and the edge control electrode 115.

In one configuration, the bias electrode 104 is a chucking pole used to secure (i.e., chuck) the substrate 103 to the substrate supporting surface 105A of the substrate support 105 and to bias the substrate 103 with respect to the plasma 101 using one or more of the pulsed-voltage biasing schemes described herein. Typically, the bias electrode 104 is formed of one or more electrically conductive parts, such as one or more metal meshes, foils, plates, or combinations thereof.

The PV source assemblies 194, 195 may also each include a clamping network 116 so that a high voltage bias applied to the bias electrode 104 and/or edge control electrode 115. In some embodiments, the bias electrode 104 is electrically coupled to a clamping network 116 and the edge electrode 115 is electrically coupled to a clamping network 116. The clamping networks provide a chucking voltage thereto, such as static DC voltage between about −5000 V and about +5000 V, using an electrical conductor, such as the coaxial power delivery line 106 (e.g., a coaxial cable). The clamping network 116 includes bias compensation circuit elements 116A, a DC power supply 155, and a bias compensation module blocking capacitor, which is also referred to herein as the blocking capacitor C₅. The blocking capacitor C₅ is disposed between the output of a pulsed voltage (PV) waveform generator 150 and the bias electrode 104. Applying similarly configured PV waveforms and clamping voltages to the bias electrode 104 and edge control electrode 115 can help improve the plasma uniformity across the surface of the substrate during processing and thus improve the plasma processing process results.

As discussed above, in some embodiments, the substrate support assembly 136 include the edge control electrode 115 that is positioned below the edge ring 114 and surrounds the bias electrode 104 and/or is disposed a distance from a center of the bias electrode 104. In general, for a processing chamber 100 that is configured to process circular substrates, the edge control electrode 115 is annular in shape, is made from a conductive material, and is configured to surround at least a portion of the bias electrode 104. In some embodiments, such as shown in FIGS. 1A-1B, the edge control electrode 115 is positioned within a region of the substrate support 105. In some embodiments, as illustrated in FIGS. 1A-1B, the edge control electrode 115 includes a conductive mesh, foil, and/or plate that is disposed a similar distance (i.e., Z-direction) from the substrate supporting surface 105A of the substrate support 105 as the bias electrode 104. In some other embodiments, the edge control electrode 115 includes a conductive mesh, foil, and/or plate that is positioned on or within a region of a quartz pipe 110, which surrounds at least a portion of the bias electrode 104 and/or the substrate support 105. Alternately, in some other embodiments (not shown), the edge control electrode 115 is positioned within or is coupled to the edge ring 114, which is disposed on and adjacent to the substrate support 105. In this configuration, the edge ring 114 is formed from a semiconductor or dielectric material (e.g., AlN, etc.).

A power delivery line 157 electrically connects the output of the PV waveform generator 150 of the PV source assembly 195 to an optional filter assembly 151 and the bias electrode 104. While the discussion below primarily discusses the power delivery line 157 of the PV source assembly 194, which is used to couple a PV waveform generator 150 to the bias electrode 104, the power delivery line 158 of the PV source assembly 195, which couples a PV waveform generator 150 to the edge control electrode 115, will include the same or similar components. The electrical conductor(s) within the various parts of the power delivery line 157 may include: (a) one or a combination of coaxial cables, such as a flexible coaxial cable that is connected in series with a rigid coaxial cable, (b) an insulated high-voltage corona-resistant hookup wire, (c) a bare wire, (d) a metal rod, (e) an electrical connector, or (f) any combination of electrical elements in (a)-(e). The optional filter assembly 151 includes one or more electrical elements that are configured to reduce, or prevent, a current generated by one or more of the plasma sources from flowing through the power delivery line 157 and damaging the PV waveform generator 150.

In some embodiments, the processing chamber 100 further includes the quartz pipe 110, or collar, that at least partially circumscribes portions of the substrate support assembly 136 to prevent the substrate support 105 and/or the support base 107 from contact with corrosive processing gases or plasma, cleaning gases or plasma, or byproducts thereof. Typically, the quartz pipe 110, the insulator plate 111, and the ground plate 112 are circumscribed by a liner 108. In some embodiments, a plasma screen 109 is positioned between the cathode liner 108 and the sidewalls 122 to prevent plasma from forming in a volume underneath the plasma screen 109 between the liner 108 and the one or more sidewalls 122.

In some embodiments, a PV waveform generator 150 can be adapted to provide a voltage waveform to a plurality of electrodes within the processing chamber 100. In some cases, the PV waveform generator 150 can be used within one or more of the plasma source assemblies 194-195. The PV waveform will typically oscillate at about 400 kilohertz (kHz). A PV waveform generator 150 will typically include a PV source controller and at least one voltage source assembly that includes a voltage source that is configured to provide a PV waveform to at least one generator output that is coupled to one or more of the electrodes and/or coils. In some embodiments, the PV waveform generator 150 is a switch-mode power supply. In some embodiments, each of the PV waveform generators 150 are configured to deliver between 10 and 25 kilowatts (KW) of DC power to a coil.

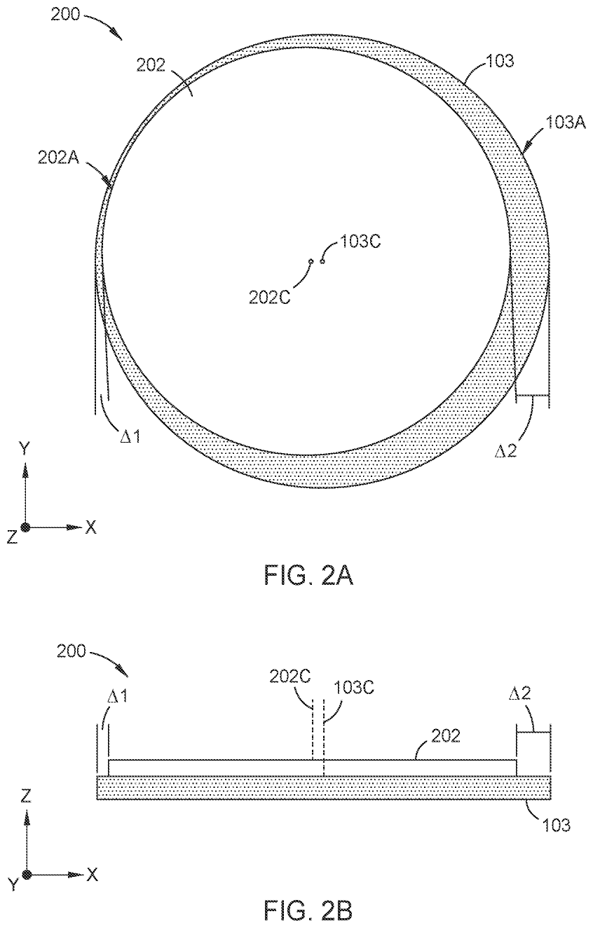

FIGS. 2A-2B are schematic views of a device substrate 200, according to one or more embodiments described herein. The device substrate 200 includes a substrate 103 with one or more layers 202 disposed thereon. The substrate 103 has a substrate outer profile 103A with a center of focus (i.e., a substrate center 103C). The one or more layers 202 have an outer profile 202A with a center of focus (i.e., a layer center 202C).

The substrate outer profile 103A and the outer profile 202A of the one or more layers are separated at any two points by a first distance, Δ1, normal to the substrate outer profile 103A and outer profile 202A, and a second distance, Δ2, normal to the substrate outer profile 103A and outer profile 202A. In this example, Δ₁ is not equal to Δ2, indicating that the substrate 103 and the one or more layers 202 are non-concentric.

As depicted in both FIG. 2A, and FIG. 2B, the lack of concentricity between the substrate 103 and the one or more layers 202 may also be visualized by the relationship between the substrate center 103C, and the layer center 202C. In this example, the substrate center 103C and the layer center 202C do not share the same point in the x-direction and the y-direction, also indicating that the substrate 103 and the one or more layers 202 are non-concentric.

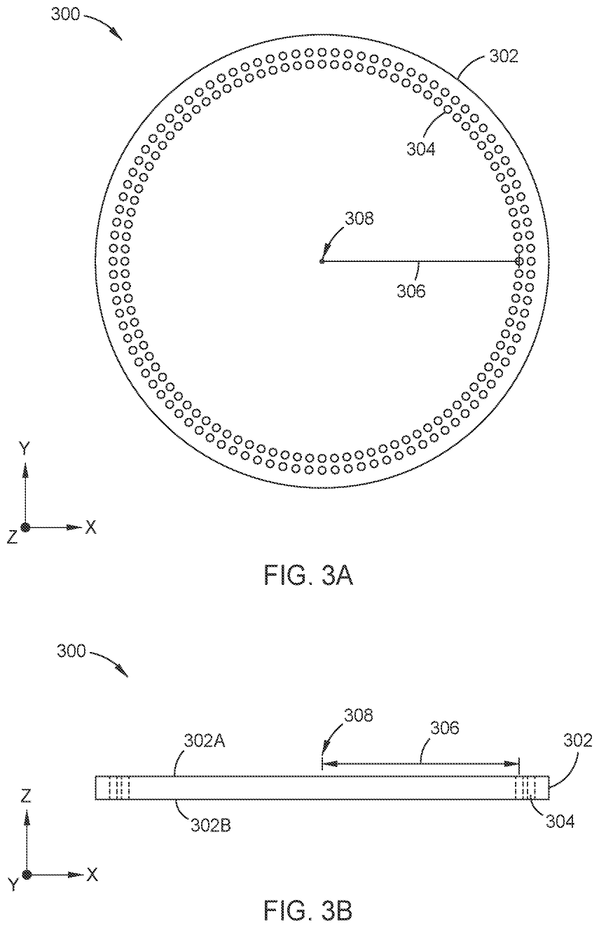

FIGS. 3A-3B are schematic views of a grid plate 300 of a plasma processing system, according to one or more embodiments described herein. One or more grid plates 300 forms a grid plate assembly. The grid plate assembly divides the processing volume into a first volume disposed above the grid assembly to receive a plasma and a second volume disposed below the grid assembly for processing a substrate.

The grid plate 300 includes a first surface 302A and a second surface 302B disposed opposite of the first surface 302A. The grid plate includes an outer profile 302 with a center of focus, (i.e., the grid plate center 308). The grid plate 300 includes a plurality of perforations 304 (e.g., two or more) extending between the first surface 302A and the second surface 302B. The plurality of perforations 304 form a first pattern of perforations 304 arranged along a circular path. The first pattern of perforations 304 also includes one or more concentric rows of perforations 304 extending along the circular path. The first pattern of perforations are disposed over a peripheral region of a substrate support surface of a substrate support from a first distance 306 to a second distance 307. Referring to FIGS. 2A-2B, the peripheral region of the substrate support surface is an area that would place the first pattern of perforations 304 from about the outer profile 202A of the one or more layers 202 to about the substrate outer profile. When more than one grid plate 300 is included in a grid assembly, the perforations 304 of each of the grid plates in the grid assembly are vertically aligned with one another. In other embodiments, the perforations of each of the grid plates in a grid assembly may be offset tangentially from one another.

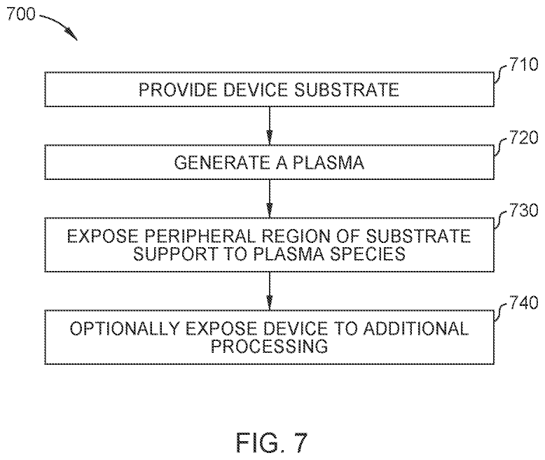

FIG. 7 is a process flow diagram of a method 700 of operations, according to one or more embodiments described herein. FIG. 7 may be understood with references to FIGS. 1A-1B, 2A-2B, 3A-3B, 4, 5, and 6.

Operation 710 of method 700 includes providing a device substrate 200. The device substrate 200 including substrate 103 with one or more layers 202 disposed thereon exhibiting non-concentricity. Providing the device substrate 200 includes loading the device substrate 200 on the substrate support surface 105A of a substrate support assembly 136 within the second volume of a processing volume 129 of a processing chamber.

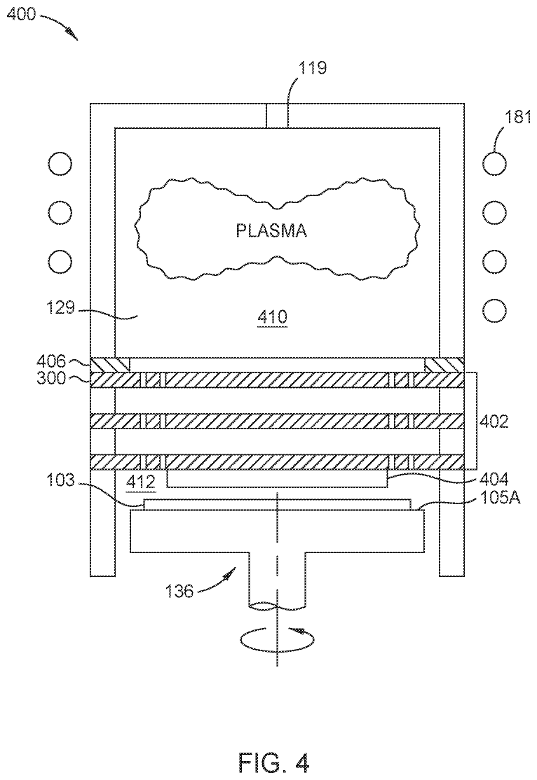

In one embodiment, shown in FIG. 4, the plasma processing system 400 includes a processing chamber having one or more sidewalls defining the processing volume 129, a grid assembly 402, a blocking plate 404, an isolation structure 406, the substrate support assembly 136, and an RF coil 181.

The plasma processing system 400 includes the grid assembly 402. The grid assembly 402 includes at least one grid plate 300. In FIG. 4, the grid assembly includes three grid plates 300. In other embodiments, there may be as few as one grid plate to as many as about ten grid plates. The grid assembly 402 divides the processing volume 129 into a first volume 410 disposed above the grid assembly 402 to receive a plasma and a second volume 412 disposed below the grid assembly for processing a substrate. The grid assembly 402 is electrically isolated from the processing chamber by one or more isolation structures 406. The plasma processing system 400 includes substrate support assembly 136 disposed within the second volume 412. The substrate support assembly 136 includes a substrate support surface 105A configured to secure a substrate 103 on the substrate support assembly 136 for processing. In some embodiments, the substrate support assembly 136 may be configured to rotate about a central axis.

In some embodiments, the plasma processing system 400 includes a blocking plate 404 disposed between the top surface of the substrate 103 and the grid assembly 402. The blocking plate 404 has an outer profile inside (i.e., smaller) the peripheral region of the substrate support surface 105A. In some embodiments, the plasma processing system 400 includes the coil 181 disposed above the grid assembly, and around the first volume 410 where the coil 181 is configured to generate an inductively coupled plasma in the first volume 410.

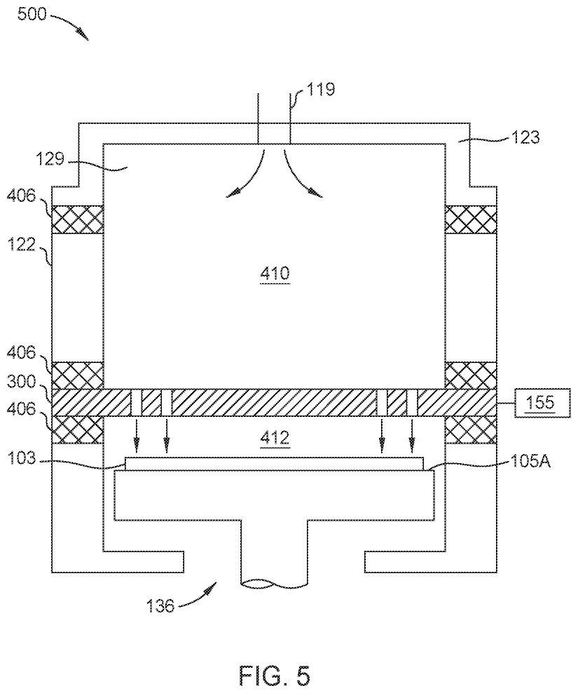

In one embodiment, shown in FIG. 5, embodiment, the plasma processing system 500 includes a processing chamber having one or more sidewalls 122 defining the processing volume 129, grid plate 300, one or more isolation structures 406, chamber lid 123, DC power supply 155, and substrate support assembly 136.

The plasma processing system 500 includes the grid plate 300. In some embodiments, additional grid plates may be present as part of a grid assembly. The grid plate 300 divides the processing volume 129 into a first volume 410 disposed above the grid plate 300 to receive a plasma and a second volume 412 disposed below the grid plate 300 for processing a substrate. In one embodiment, the grid plate 300, or more than one grid plate in a grid assembly, is electrically isolated from the processing chamber by one or more isolation structures 406. In some embodiments, the grid plate 300, or more than one grid plate in a grid assembly, is in electrical communication with the DC power supply 155 allowing the grid plate 300, or more than one grid plate in a grid assembly, to be biasable in relation to the chamber lid 123, or other component of the plasma processing system. The bias applied to the grid plate 300, or more than one grid plate in a grid assembly, in relation to the chamber lid 123 is between about negative 0.1 V to about negative 10 kV, for example, about negative 6 kV. In other embodiments, the grid plate 300, or more than one grid plate in a grid assembly may be electrically grounded in relation to the chamber lid 123, or other component of a plasma processing system. The chamber lid 123 is disposed above the sidewalls 122 and electrically isolated from the sidewalls 122 by one or more isolation structures 406. The plasma processing system 500 includes substrate support assembly 136 disposed within the second volume 412. The substrate support assembly 136 includes a substrate support surface 105A configured to secure a substrate 103 on the substrate support assembly 136 for processing.

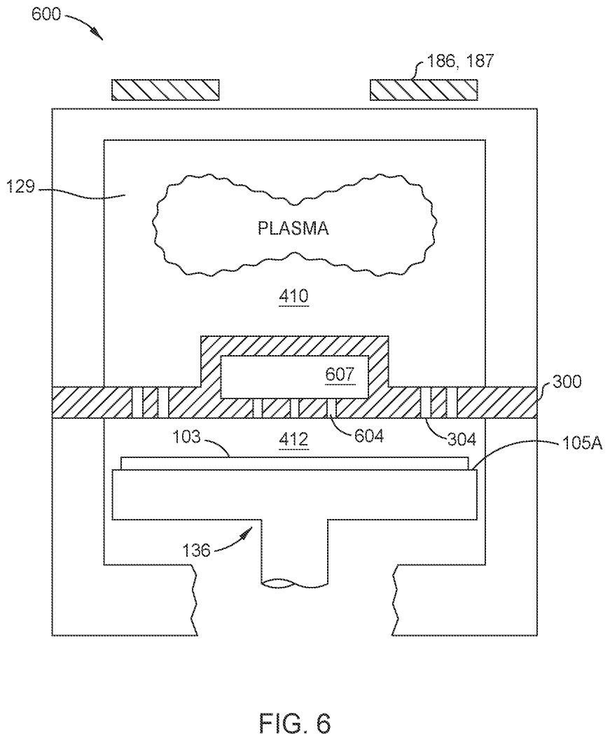

In another embodiment, shown in FIG. 6, the plasma processing system 600 includes a processing chamber having one or more sidewalls 122 defining the processing volume 129, grid plate 300, and substrate support assembly 136. The plasma processing system 600 includes the grid plate 300. In some embodiments, additional grid plates may be present as part of a grid assembly. The grid plate 300 divides the processing volume 129 into a first volume 410 disposed above the grid plate 300 to receive a plasma and a second volume 412 disposed below the grid plate 300 for processing a substrate. The plasma processing system 600 includes substrate support assembly 136 disposed within the second volume 412. The substrate support assembly 136 includes a substrate support surface 105A configured to secure a substrate 103 on the substrate support assembly 136 for processing. In this embodiment, the grid plate 300 includes a cavity 607 and one or more gas channels 604. The cavity 607 and one or more gas channels 604 are configured to deliver a gas to the central region (i.e., the region within the peripheral region) of the substrate support surface 105A.

Operation 720 of method 700 includes generating a plasma in a plasma-processing region (e.g., the first volume 410) of a processing volume 129 of a processing chamber. In one embodiment, generating a plasma in the first volume 410 of the processing volume 129 includes generating a vacuum in the processing volume 129, for example between about 0.1 milli-Torr (mTorr) to about 15 mTorr, delivering an RF waveform to one or more ICP assemblies, such as coil 181, to generate an inductively coupled plasma. In some embodiments, generating a plasma in the first volume 410 of the processing volume 129 includes delivering an RF waveform to one or more CCP assemblies to generate a capacitively coupled plasma. In other embodiments, generating a plasma may include grounding the substrate support assembly 136 and applying a voltage to the chamber lid 123. The voltage applied to the chamber lid may be between about 0.1 V to about 10 kV, for example, about 6 kV. In other embodiments, generating a plasma may include biasing the substrate support assembly 136.

Operation 730 of method 700 includes exposing the peripheral region of the substrate support surface 105A to a plasma species (i.e., ions, electrons, charged particles and/or molecules) generated in the plasma in the first volume 410 by focusing the plasma species through the plurality of perforations 304 onto the peripheral region of the substrate support surface 105A.

Exposing the peripheral region of the substrate support surface 105A also exposes an area of a substrate 103 disposed on the substrate support surface 105A from about the outer profile 202A of the one or more layers 202 to about the substrate outer profile 103A to the plasma species generated in the plasma in the first volume through the plurality of perforations 304. The remainder of the substrate 103 and substrate support surface 105A are protected from the plasma species by the solid portions of the grid plate, or grid plates. The exposure to the plasma species etches the outer profile 202A of the one or more layers 202, the substrate outer profile 103A, or both. By etching the outer profile 202A of the one or more layers 202, the substrate outer profile 103A, or both, concentricity between the substrate outer profile 103A and the outer profile 202A can be improved. In some embodiments, the substrate support assembly 136 is configured to rotate about a central axis during the exposure to the plasma species to improve concentricity between the substrate outer profile 103A and the outer profile 202A. At operation 740 of method 700, the device substrate 200 may be exposed to additional processing.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up” “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A plasma processing system, comprising:
a processing chamber comprising one or more sidewalls defining a processing volume; and
a grid assembly comprising one or more grid plates, wherein the grid assembly divides the processing volume into a first volume disposed above the grid assembly to receive a plasma and a second volume disposed below the grid assembly for processing a substrate, wherein each grid plate of the one or more grid plates comprises:
a first surface;
a second surface, disposed opposite of the first surface; and
a plurality of perforations extending between the first surface and the second surface, wherein the plurality of perforations comprise:
a first pattern of two or more perforations arranged along a circular path disposed over a peripheral region of a substrate support surface of a substrate support assembly disposed in the second volume, the first pattern further comprising:
one or more concentric rows of perforations, wherein each row of the one or more concentric rows is spaced radially from a center of the one or more grid plates,
each row of the one or more concentric rows include at least one perforation;
wherein the plurality of perforations of each grid plate of the one or more grid plates are vertically aligned to the plurality of perforations of each other grid plate of the one or more grid plates.

2. The plasma processing system of claim 1, wherein the plurality of perforations of each grid plate of the one or more grid plates are tangentially offset from the plurality of perforations of at least one grid plate of the one or more grid plates.

3. The plasma processing system of claim 1, further comprising a blocking plate disposed between a substrate support surface of a substrate support assembly disposed within the second volume and the grid assembly, wherein the blocking plate has an outer profile inside the peripheral region of the substrate support surface.

4. The plasma processing system of claim 1, wherein the processing chamber further comprises one or more inductively-coupled plasma (ICP) assemblies disposed above the processing volume configured to generate an ICP plasma in the first volume.

5. The plasma processing system of claim 1, further comprising a radio frequency (RF) coil disposed above the grid assembly, around the first volume, and configured to generate a plasma in the first volume.

6. The plasma processing system of claim 1, wherein the processing chamber further comprises one or more capacitively coupled plasma (CCP) assemblies configured to generate a CCP plasma in the first volume.

7. The plasma processing system of claim 1, wherein at least one grid plate of the one or more grid plates is electrically isolated from the processing chamber.

8. The plasma processing system of claim 1, wherein at least one grid plate of the one or more grid plates is electrically grounded in relation to a component of the plasma processing system.

9. The plasma processing system of claim 1, wherein at least one grid plate of the one or more grid plates is electrically biasable in relation to a component of the plasma processing system.

10. The plasma processing system of claim 1, wherein at least one grid plate of the one or more grid plates further comprises one or more gas channels configured to deliver a gas to a central region of the substrate support surface.

11. The plasma processing system of claim 1, wherein the substrate support assembly is configured to rotate about a central axis.

12. A method of substrate processing, comprising:
generating a plasma in a plasma processing region of a processing volume of a processing chamber,
wherein the processing volume is defined by a chamber lid, a chamber base, and one or more sidewalls,
wherein the processing volume comprises a first volume disposed above a grid assembly to receive a plasma and a second volume disposed below the grid assembly for processing a substrate, wherein the grid assembly comprises one or more grid plates, wherein each grid plate of the one or more grid plates comprises:
a first surface;
a second surface, disposed opposite of the first surface; and
a plurality of perforations extending between the first surface and the second surface, wherein the plurality of perforations comprise
a first pattern of two or more perforations arranged along a circular path disposed over a peripheral region of a substrate support surface of a substrate support assembly disposed in the second volume, the first pattern further comprising:
one or more concentric rows of perforations, wherein
each row of the one or more concentric rows is spaced radially from a center of the grid plate,
each row of the one or more concentric rows include at least one perforation;
wherein the plurality of perforations of each grid plate of the one or more grid plates are vertically aligned to the plurality of perforations of each other grid plate of the one or more grid plates; and
exposing the peripheral region of the substrate support surface to a plasma species generated in a plasma in the first volume by focusing the plasma species through the plurality of perforations onto the peripheral region of the substrate support surface.

13. The method of claim 12, wherein exposing the peripheral region of the substrate support surface to a plasma species generated in a plasma in the first volume further comprises:
etching a peripheral region of a device substrate disposed upon the substrate support surface using the plasma species focused through the plurality of perforations onto the peripheral region of the substrate support surface,
wherein the peripheral region of the device substrate comprises an area between about an outer profile of the device substrate and about an outer profile of one or more layers disposed on the substrate, and
wherein the etching improves a concentricity between the outer profile of the device substrate and the outer profile of one or more layers disposed on the substrate.

14. The method of claim 12, further comprising rotating the substrate support assembly about a central axis.

15. The method of claim 12, further comprising electrically grounding at least one grid plate of the one or more grid plates in relation to the processing volume.

16. The method of claim 12, further comprising electrically isolating at least one grid plate of the one or more grid plates in relation to processing volume.

17. The method of claim 12, further comprising a blocking plate disposed between a substrate support surface of a substrate support assembly disposed within the second volume and the grid assembly, wherein the blocking plate has an outer profile inside the peripheral region of the substrate support surface.

18. The method of claim 12, wherein focusing the plasma species through the plurality of perforations onto the peripheral region of the substrate support surface further comprises:
delivering a process gas to the processing volume, wherein the process gas comprises a mixture of at least an inert gas, a fluorine-containing gas, and a hydrogen-containing gas; and
generating a plasma in the plasma processing region by excitation of the process gas by one or more inductively-coupled plasma (ICP) assemblies disposed above a chamber lid.

19. The method of claim 18, further comprising generating a plasma in the plasma processing region by excitation of a process gas by a radio frequency (RF) coil disposed around the plasma processing region outside of the processing volume.

20. The method of claim 12, wherein focusing the plasma species through the plurality of perforations onto the peripheral region of the substrate support surface further comprises:
delivering a process gas to the processing volume, wherein the process gas comprises at least an inert gas; and
generating a plasma in the plasma processing region by excitation of a process gas by one or more capacitively coupled plasma (CCP) assemblies configured to generate a CCP plasma above the grid assembly.

21. The method of claim 12, wherein focusing the plasma species through the plurality of perforations onto the peripheral region of the substrate support surface further comprises:
accelerating the plasma species through the plurality of perforations, wherein accelerating the plasma species comprises:
electrically isolating a chamber lid disposed above the first volume from the one or more sidewalls, the chamber base, the chamber lid
applying a first voltage to the chamber lid, wherein the first voltage is between about 0.1 V to about 6 kV;
electrically isolating the grid assembly from the one or more sidewalls, the chamber base, the chamber lid;
applying a second voltage to at least one grid plate of the one or more grid plates, wherein the second voltage is between about negative 0.1 V to about negative 6 kV; and
grounding the substrate support assembly.

22. The method of claim 21, wherein applying the second voltage to at least one grid plate of the one or more grid plates further comprises applying the second voltage as a pulsed voltage waveform.

23. The method of claim 21, wherein applying the second voltage to at least one grid plate of the one or more grid plates further comprises applying the second voltage as a sinusoidal voltage waveform.

24. The method of claim 21, wherein at least one grid plate of the one or more grid plates further comprises one or more gas channels configured to deliver a gas to a central region of the substrate support surface.
